(19) United States
(12) Patent Application Publication
(10) Pub. No.: US 2016/0372306 A1
(43) Pub. Date: Dec. 22, 2016

(54) Method for Controlling Plasma Uniformity in Plasma Processing Systems

(71) Applicant: Tokyo Electron Limited, Tokyo (JP)

(72) Inventors: Sergey Voronin, Delmar, NY (US); Alok Ranjan, Mechanicville, NY (US)

(21) Appl. No.: 14/944,927

(22) Filed: Nov. 18, 2015

Related U.S. Application Data
(60) Provisional application No. 62/181,568, filed on Jun. 18, 2015.

(51) Int. Cl. H01J 37/32

(52) U.S. Cl. CPC H01J 37/3211; H01J 37/3244; H01J 37/32183; H01J 2237/3341; H01J 2237/3323

(57) ABSTRACT

Techniques herein include a method for generating uniform plasma within an inductively-coupled plasma reactor. Techniques herein include providing a termination capacitor that is dynamically adjustable to adjust a termination capacitor value to provide a uniform E-field distribution in the reactor via a time-averaged uniformity. During a given plasma processing operation, a termination capacitor can be continuously changed to create various rotational cycles so that a given substrate received uniform treatment.

### CROSS REFERENCE TO RELATED APPLICATIONS

The present application claims the benefit of U.S. Provisional Patent Application No. 62/181,568, filed on Jun. 18, 2015, entitled “Method for Controlling Plasma Uniformity in Plasma Processing Systems,” which is incorporated herein by reference in its entirety.

### BACKGROUND OF THE INVENTION

This disclosure relates to plasma processing systems.

Fabrication of integrated circuits (IC) in the semiconductor industry typically employs plasma to create and assist surface chemistry necessary to remove material from and deposit material to a substrate within a plasma processing chamber. In general, plasma is formed within the plasma reactor under vacuum conditions by heating electrons to energies sufficient to sustain ionizing collisions with a supplied process gas. Moreover, the heated electrons can have energy sufficient to sustain dissociative collisions and, therefore, a specific set of gases under predetermined conditions (e.g., chamber pressure, gas flow rate, etc.) are chosen to produce a population of charged species and/or chemically reactive species suitable to a particular process being performed within the chamber (e.g., etching processes where materials are removed from the substrate or deposition processes where materials are added to the substrate).

### SUMMARY

Inductively coupled plasma (ICP) etching reactors are widely used in the semiconductor industry. Providing high plasma densities for a wide range of processing pressures, ICP systems can operate as large-scale plasma reactors due to flexibility in the antenna coil configuration design. In general these devices tend to have uniform etch rates across the wafer, but with some side to side and azimuthal variations. One source of plasma non-uniformity in ICP discharges is a standing wave effect. Such a standing wave effect can occur when the operating radio frequency wavelength is comparable with the coil and chamber dimensions. The electrical field of the antenna can have local minimum(s) and maximum(s) within the coil resulting in non-uniform ionization and plasma non-uniformity.

Techniques herein include providing a termination capacitor that is dynamically adjustable to adjust a termination capacitor value (i.e. using a variable capacitor) to provide a uniform E-field distribution in the reactor via a “time-averaged” uniformity.

One embodiment includes a method for plasma processing to generate uniform plasma treatments. A process gas is flowed into a plasma processing chamber. The plasma processing chamber is an inductively-coupled plasma processing system in that the plasma processing system includes a radio frequency generator, an antenna coil, and a terminating capacitor coupled to the antenna coil. Plasma is maintained in the plasma processing chamber from the process gas by energizing the antenna coil with a radio frequency current. The plasma has azimuthal variations in density with a static terminal capacitor. Continuously changing a capacitance value of the terminating capacitor while plasma is being maintained in the plasma processing chamber such that an electric field distribution rotates within the plasma processing chamber.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of various embodiments of the invention and many of the attendant advantages thereof will become readily apparent with reference to the following detailed description considered in conjunction with the accompanying drawings. The drawings are not necessarily to scale, with emphasis instead being placed upon illustrating the features, principles and concepts.

FIG. 1 is a schematic cross sectional view of an inductively coupled plasma processing apparatus in accordance with embodiments herein.

FIG. 2 is a schematic diagram of a single turn coil with variable capacitor in accordance with embodiments herein.

FIG. 3 is a schematic diagram of variable capacitors in parallel in accordance with embodiments herein.

FIG. 4 is a schematic diagram of a multiple turn coil with variable capacitor in accordance with embodiments herein.

FIG. 5 is a schematic diagram of a multiple turn double coil with variable capacitor in accordance with embodiments herein.

FIG. 6 is a flow chart of a method for providing uniform plasma treatment according to embodiments disclosed herein.

### DETAILED DESCRIPTION

Techniques herein include a method for generating uniform plasma within an inductively-coupled plasma reactor. Techniques herein include providing a termination capacitor that is dynamically adjustable to adjust a termination capacitor value (i.e. using a variable capacitor) to provide a uniform E-field distribution in the reactor via a “time-averaged” uniformity.

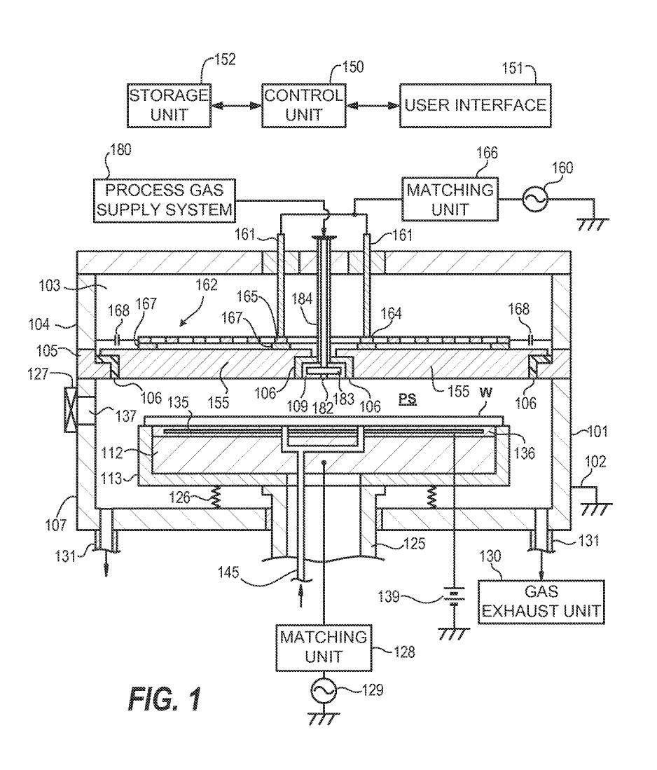

FIG. 1 is a schematic cross-sectional view of an inductively coupled plasma processing apparatus in accordance with embodiments herein. This apparatus can be used for multiple operations including ashing, etching, and deposition. Plasma processing can be executed within processing chamber 101, which can be a vacuum chamber made of a metal such as aluminum or stainless steel. The processing chamber 101 is grounded such as by ground wire 102. The processing chamber 101 defines a processing vessel providing a process space PS for plasma generation. An inner wall of the processing vessel can be coated with alumina, yttria, or other protectant. The processing vessel can be cylindrical, square, column-shaped, etc.

At a lower, central area within the processing chamber 101, a susceptor 112 (which can be disc-shaped) can serve as a mounting table on which, for example, a substrate W to be processed (such as a semiconductor wafer) can be mounted. Substrate W can be moved into the processing chamber 101 through loading/unloading port 137 and gate valve 127. The susceptor 112 can be made of a conductive material. Susceptor 112 is provided thereon with an electrostatic chuck 136 for holding the substrate W. The electrostatic chuck 136 is provided with an electrode 135. Electrode 135 is electrically connected to DC power source 139 (direct current power source). The electrostatic chuck 136 attracts the substrate W thereto via an electrostatic force generated when DC voltage from the DC power source 139 is applied to the electrode 135 so that substrate W is securely mounted on the susceptor 112. The susceptor 112 can include an insulating frame 113 and be supported by support 125, which can include an elevation mechanism. The susceptor 112 can be vertically moved by the elevation mechanism during loading and/or unloading of the substrate W. A bellows 126 can be disposed between the insulating frame 113 and a bottom portion of the processing chamber 101 to surround support 125 as an airtight enclosure. Susceptor 112 can include a temperature sensor and a temperature control mechanism including a coolant flow path, a heating unit such as a ceramic heater or the like (all not shown) that can be used to control a temperature of the substrate W. A focus ring (not shown), can be provided on an upper surface of the susceptor 112 to surround the electrostatic chuck 136 and assist with directional ion bombardment.

A gas supply line 145, which passes through the susceptor 112, is configured to supply heat transfer gas to an upper surface of the electrostatic chuck 136. A heat transfer gas (also known as backside gas) such as helium (He) can be supplied between the substrate W and the electrostatic chuck 136 via the gas supply line 145 to assist in heating substrate W.

A gas exhaust unit 130 including a vacuum pump and the like can be connected to a bottom portion of the processing chamber 101 through gas exhaust line 131. The gas exhaust unit 130 can include a vacuum pump such as a turbo molecular pump configured to decompress the plasma processing space within the processing chamber 101 to a desired vacuum condition during a given plasma processing operation.

The plasma processing apparatus can be horizontally partitioned into an antenna chamber 103 and a processing chamber 101 by a window 155. Window 155 can be a dielectric material, such as quartz, or a conductive material, such as metal. For embodiments in which the window 155 is metal, the window 155 can be electrically insulated from processing chamber 101 such as with insulators 106. In this example, the window 155 forms a ceiling of the processing chamber 101. In some embodiments, window 155 can be divided into multiple sections, with these sections optionally insulated from each other.

Provided between sidewall 104 of the antenna chamber 103 and sidewall 107 of the processing chamber 101 is a support shelf 105 projecting toward the inside of the processing apparatus. A support member 109 serves to support window 155 and also functions as a shower housing for supplying a processing gas. When the support member 109 serves as the shower housing, a gas channel 183, extending in a direction parallel to a working surface of a substrate W to be processed, is formed inside the support member 109 and communicates with gas injection openings 182 for injecting process gas into the process space PS. A gas supply line 184 is configured to be in communication with the gas channel 183. The gas supply line 184 defines a flow path through the ceiling of the processing chamber 101, and is connected to a process gas supply system 180 including a processing gas supply source, a valve system and the corresponding components. Accordingly, during plasma processing, a given process gas can be injected into the process space PS.

In antenna chamber 103, a high-frequency antenna 162 (radio frequency) is disposed above the window 155 so as to face the window 155, and can be spaced apart from the window 155 by a spacers 167 made of an insulating material. High-frequency antenna 162 can be formed in a spiral shape or formed in other configurations.

During plasma processing, a high frequency power having a frequency of, e.g., 13.56 MHz, for generating an inductive electric field can be supplied from a high-frequency power source 160 to the high-frequency antenna 162 via power feed members 161. A matching unit 166 (impedance matching unit) can be connected to high-frequency power source 160. The high-frequency antenna 162 in this example can have corresponding power feed portion 164 and power feed portion 165 connected to the power feed members 161, as well as additional power feed portions depending on a particular antenna configuration. Power feed portions can be arranged at similar diametrical distances and angular spacing. Antenna lines can extend outwardly from power feed portion 164 and power feed portion 165 (or inwardly depending on antenna configuration) to an end portion of antenna lines. End portions of antenna lines are connected to the capacitors 168, and the antenna lines are grounded via the capacitors 168. Capacitors 168 can including one or more variable capacitors as disclosed herein and described in more detail below.

With a given substrate mounted within processing chamber 101, one or more plasma processing operations can be executed. By applying high frequency power to the high-frequency antenna 162, an inductive electric field is generated in the processing chamber 101, and processing gas supplied from the gas injection openings 182 is turned into a plasma by the inductive electric field. The plasma can then be used to process a given substrate such as by etching, ashing, deposition, etc.

High-frequency power source 129 (as second high-frequency power source) is connected to the susceptor 112 via a matching unit 128. The high-frequency power source 129 supplies a high frequency bias power having a frequency of, e.g., 3.2 MHz (or other frequency), to the mounting table during plasma processing. Applying high frequency bias power causes ions, in plasma generated in the processing chamber, to be attracted to substrate W.

Components of the plasma processing apparatus can be connected to, and controlled by, a control unit 150, which in turn can be connected to a corresponding storage unit 152 and user interface 151. Various plasma processing operations can be executed via the user interface 151, and various plasma processing recipes and operations can be stored in storage unit 152. Accordingly, a given substrate can be processed within the plasma processing chamber with various microfabrication techniques.

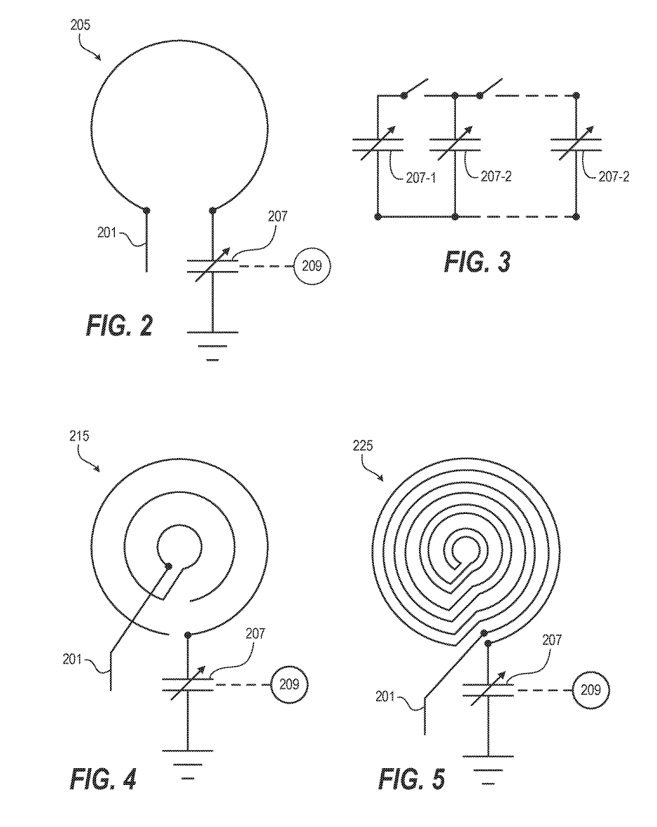

The electric field (E-field) distribution in an inductively coupled plasma can be related to termination capacitance. FIG. 2 shows a simplified schematic of ICP power. RF power input 201 supplies RF power to single turn coil 205, which is connected to termination capacitor 207. RF power through the coil induces an E-field, which creates plasma from a supplied process gas.

This E-field, however, is typically not uniform. Azimuthal symmetry of an electric field can improve with increasing termination capacitance while a peak in the electric field rotates in angle. For high operating RF frequencies, a wavelength becomes comparable with the coil and chamber dimensions. This means that a standing wave effect results in E-field non-uniformity. Termination capacitance can determine the location of voltage zero crossings and current maxima in the standing wave along a transmission line. Modifying the termination capacitance herein, helps achieve E-field azimuthal symmetry. By continuously (cycling) changing a termination capacitance herein results in a rotating E-field maximum. Having a rotating E-field means improvement of “time-averaged” plasma uniformity. For example, at any given point in a plasma processing operation, there may not exist a uniform plasma, but the non-uniformities can rotate around a substrate so that on average (over a period of time), each location on a given substrate is exposed to a uniform plasma treatment.

Embodiments herein can include multiple different configurations. One configuration includes a single turn coil 205 that includes motor 209 configured to change or vary capacitance of termination capacitor 207, as shown in FIG. 2. Other embodiments can include multiple turn coil 215, as shown in FIG. 4, or multiple turn double coil 225, as shown in FIG. 5. Motor 209 can include a step motor or solenoid-driven variable capacitor, or any other type of fast variable capacitor (or reactive load) can be used herein. Moreover, a given variable capacitor can include a number of capacitors in parallel connected to each other through switches, as can be seen with termination capacitors 207-1, 207-2, and 207-3 in FIG. 3. Accordingly, continuous (cycling) changing of termination capacitance (or a variable reactive load) can result in a rotating E-field maximum, which in turn provides a time-averaged plasma uniformity. Capacitance change periods can be based on characteristics of a given plasma treatment process, such as type of process (deposition or etching), duration of process, process gas used, etc. Exemplary capacitance changing periods can range between a few milliseconds to seconds.

Conventional plasma processing recipes commonly range from having process recipe step times that are between a few seconds to a few dozen seconds. As such, a given electric field rotation period herein should be selected to be shorter than a given recipe time. For example, for a recipe having plasma treatment that is less than a second, then a reactive load impedance cycling frequency can be set to tens of Hertz or rotational cycles per second (rotational frequency). For a given plasma treatment having a relatively longer processing duration (tens of seconds), a corresponding reactive load can be configured to oscillate on a frequency of about one Hertz or rotational cycle per second (rotational frequency). Note that a terminating load value can be caused to change many times over one process step. Accordingly, such techniques provide azimuthal plasma density uniformity improvement.

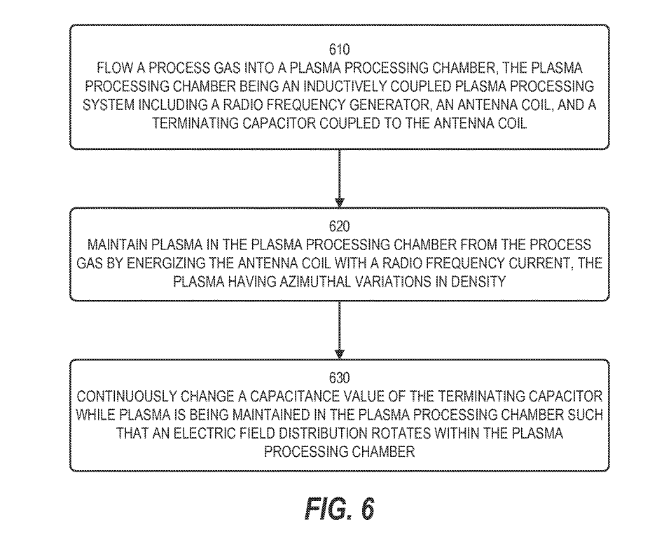

FIG. 6 shows a flow chart for generating uniform plasma treatment according to embodiments disclosed herein. In step 610, process gas is flowed into a plasma processing chamber, such as processing chamber 101 112104. The plasma processing chamber is an inductively coupled plasma processing system in that the plasma processing system includes a radio frequency generator, an antenna coil, and a terminating capacitor coupled to the antenna coil. Note that the antenna coil can be embodied using multiple different geometries and thus is not necessarily a symmetrical coil.

In step 620, plasma is maintained in the plasma processing chamber from the process gas by energizing the antenna coil with a radio frequency current. The plasma has azimuthal variations in density. In other words, without using techniques herein, the plasma has non-uniformities.

In step 630, a capacitance value of the terminating capacitor is continuously changed while plasma is being maintained in the plasma processing chamber. Dynamically varying the capacitance value is such that an electric field distribution rotates within the plasma processing chamber.

Continuously changing a capacitance value of the terminating capacitor can include causing an E-field rotation period of full rotation to be shorter than a recipe duration of a corresponding plasma processing treatment. In another embodiment, continuously changing the capacitance value of the terminating capacitor can include terminating load changes multiple times within one plasma processing step.

In other embodiments, a reactive load oscillates at a frequency of approximately 1-100 rotational cycles per second for etch steps having a duration less than about 10 seconds. Moreover, a reactive load oscillates at a frequency of approximately 1 rotational cycle per second for etch steps having a duration greater than about 10 seconds. Note, however, that plasma processing steps (etch, deposition, etc.) having a duration greater than about 10 seconds can nevertheless have 1-100 rotational cycles per second or more, or less than 10 rotational cycles per second. Continuously changing the capacitance value of the terminating capacitor can include using a step motor or solenoid-driven variable capacitor. In another embodiments, multiple capacitors configured in parallel and connected to each other through switches can be used to dynamically vary the capacitance. In other embodiments, continuously changing the capacitance value of the terminating capacitor includes coupling a dithered signal to the terminating capacitor. As can be appreciated, there are multiple different rotational schemes and hardware alternatives to dynamically change capacitance of an ICP system to provide plasma uniformity over time.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method for plasma processing, the method comprising:
flowing a process gas into a plasma processing chamber, the plasma processing chamber being an inductively-coupled plasma processing system in that the plasma processing system includes a radio frequency generator, an antenna coil, and a terminating capacitor coupled to the antenna coil;
maintaining plasma in the plasma processing chamber from the process gas by energizing the antenna coil with a radio frequency current, the plasma having azimuthal variations in density; and
continuously changing a capacitance value of the terminating capacitor while plasma is being maintained in the plasma processing chamber such that an electric field distribution rotates within the plasma processing chamber.

2. The method of claim 1, wherein continuously changing the capacitance value of the terminating capacitor includes causing an electric field rotation period of full rotation to be shorter than a recipe duration of a corresponding plasma processing treatment.

3. The method of claim 1, wherein continuously changing the capacitance value of the terminating capacitor includes terminating load changes multiple times within a corresponding plasma processing step.

4. The method of claim 1, wherein a reactive load oscillates at a frequency of approximately 1-100 rotational cycles per second for etch steps having a duration less than 10 seconds.

5. The method of claim 1, wherein a reactive load oscillates at a frequency of approximately 1 rotational cycle per second for plasma processing steps having a duration greater than 10 seconds.

6. The method of claim 1, wherein continuously changing the capacitance value of the terminating capacitor includes using a step motor or solenoid-driven variable capacitor.

7. The method of claim 1, wherein continuously changing the capacitance value of the terminating capacitor includes using a variable capacitor that includes multiple capacitors configured in parallel and connected to each other through switches.

8. The method of claim 1, continuously changing the capacitance value of the terminating capacitor includes coupling a dithered signal to the terminating capacitor.
